(19) United States
(12) Patent Application Publication
(10) Pub. No.: US 2007/0212839 A1
(43) Pub. Date: Sep. 13, 2007

(54) METHOD FOR FABRICATING SEMICONDUCTOR DEVICE

(76) Inventors: Chao-Hsi Chung, Hsinchu County (TW); Wen-Shuo Kuo, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,928

(22) Filed: May 26, 2006

(30) Foreign Application Priority Data
Mar. 10, 2006 (TW) 95108076

(51) Int. Cl. H01L 21/336

(52) U.S. Cl. 438/299

(57) ABSTRACT

A method for fabricating a semiconductor device is described. A gate dielectric layer is formed on a substrate. A plurality of gate structures are formed on the gate dielectric layer. Each of the gate structures is composed of a stacked structure and a spacer. Each stacked structure includes a gate conductive layer and a cap layer. The spacer includes a first dielectric layer and a second dielectric layer. A barrier layer is formed over the substrate covering conformally the gate structures and the gate dielectric layer. A dielectric layer is formed on the barrier layer. A self-aligned contact window etching process is conducted to form a contact window opening. A SEG process is conducted to grow an epitaxial silicon layer to form a contact window and an air gap in the opening.

### CROSS-REFERENCE TO RELATED APPLICATION

This application claims the priority benefit of Taiwan application serial no. 95108076, filed on Mar. 10, 2006. All disclosure of the Taiwan application is incorporated herein by reference.

### BACKGROUND OF THE INVENTION

1. Field of the Invention

The present invention relates to a method for fabricating a semiconductor device, and particularly to a method for fabricating a semiconductor device that is adapted for lowering parasitic capacitance thereof.

2. Description of Related Art

Along with the development of semiconductor technology, the sizes of the semiconductor devices have become smaller and smaller. While integrated circuits (IC) become denser to a certain degree, e.g., micrometer scale, the surface area of such a semiconductor chip is far from enough for allowing required interconnects set up. An approach addressing thereto for a very large scale integration (VLSI) is employing multi-layer metallic interconnects.

Unfortunately, there is often an unwanted so-called parasitic capacitance occurred between a double-layer conductive structure having a dielectric layer sandwiched therebetween, i.e., a conductor/dielectric/conductor layer stacked structure. For example, when processing a memory device, a dielectric layer is often formed on a gate electrode, and thereafter a bit-line is formed on the dielectric layer, thus a parasitic capacitance is very likely to occur therebetween according to a bit-line coupling effect.

Such a parasitic capacitance often raises a signal noise that affects the workability and even the reliability of the device. Therefore, what is needed is to lower parasitic capacitances in the IC.

Approaches to lower the parasitic capacitances in ICs are disclosed in some US patents and publications, e.g., U.S. Pat. Nos. 6,686,636, 6,960,808, and 5,510,645, and “A Gate-side Air-air Gap Structure (GAS) to Reduce the Parasitic Capacitance in MOSFETs”, M. Togo, A. Tanabe, A. Furukawa, K Tokunaga, and T Hashimoto, 1996, P. 38, all of which are cross-referred herewith by the present invention.

### SUMMARY OF THE INVENTION

An object of the present invention is to provide a method for fabricating a semiconductor device adapted for lowering parasitic capacitance thereof.

Another object of the present invention is to provide a method for fabricating a semiconductor device adapted for lowering parasitic capacitance caused by a bit-line coupling effect.

One embodiment of the present invention provides a method for fabricating a semiconductor device; the method includes the following steps. First, a gate dielectric layer is formed on a substrate. Next, a plurality of gate structures is formed on the gate dielectric layer. Each of the gate structures is composed of a stacked structure and a spacer. Each stacked structure includes a gate conductive layer and a cap layer. The spacer is formed on the sidewall of the stacked structure, and includes a first dielectric layer and a second dielectric layer. Then a barrier layer is formed over the substrate covering the gate structures and the gate dielectric layer. Thereafter, a dielectric layer is formed on the barrier layer. Next, a self-aligned contact window etching process is conducted to form a contact window opening in a portion of the dielectric layer between a pair of adjacent gate structures, and wherein the contact window opening exposes the substrate therefrom. The self-aligned contact window etching process removes portions of the dielectric layer, the barrier layer, the cap layer, the gate dielectric layer, and the spacer to form an opening in the second dielectric layer of the spacer. Next, a selective epitaxial growth (SEG) process is conducted on the substrate exposed by the contact window opening to grow an epitaxial silicon layer, thus forming a contact window and an air gap in the opening.

Another embodiment of the present invention provides a method for fabricating a semiconductor device; the method includes the following steps. First, a substrate having a memory cell region and a peripheral circuit region is provided. A gate dielectric layer is then formed on the substrate. Next, a plurality of stacked structures are formed on the substrate. Each stacked structure includes a gate conductive layer and a cap layer. A first spacer is formed on a sidewall of each stacked structure in the memory cell region, and a second spacer is formed on a sidewall of each stacked structure in the peripheral circuit region. The first spacer includes a first dielectric layer and a second dielectric layer, and the second spacer includes a third dielectric layer, a fourth dielectric layer and a fifth dielectric layer. Next, a barrier layer is formed over the substrate covering the stacked structures, the first spacer, the second spacer, and the gate dielectric layer. Thereafter, a dielectric layer is formed on the barrier layer. Next, a self-aligned contact window etching process is conducted to form a contact window opening in a portion of the dielectric layer between a pair of adjacent stacked structures in the memory cell region. The contact window opening exposes a portion of the substrate. The self-aligned contact window etching process removes portions of the dielectric layer, the barrier layer, the cap layer, the gate dielectric layer, and the first spacer to form an opening within the second spacer. Next, a selective epitaxial process is conducted on the substrate exposed by the contact window opening to grow an epitaxial silicon layer to form a contact window and an air gap in the opening.

Yet another embodiment of the present invention provides a method for fabricating a semiconductor device; the method includes the following steps. First, a first gate structure and a second gate structure are formed on a substrate. Each of the first gate structure and the second gate structure includes a gate conductive layer, a first dielectric layer formed on a sidewall of the gate conductive layer, and a second dielectric layer formed on the first dielectric layer. A barrier layer is formed over the substrate covering the first gate structure and the second gate structure. Next, a dielectric layer is formed on the barrier layer. Next, the dielectric layer and the barrier layer located between the first gate structure and the second gate structure are removed to expose a portion of the substrate to form a first opening. Portions of the first dielectric layer, the second dielectric layer and the barrier layer between the first gate structure and the second structure are removed to form a second opening between the first dielectric layer and the barrier layer. The proportion of the second dielectric layer removed is greater than that of the first dielectric layer and the barrier layer. Next, a selective epitaxial process is conducted on the substrate exposed by the first opening to grow up an epitaxial silicon layer while the second opening is not entirely filled and thereby forming an air gap in situ.

The above-mentioned methods are adapted for lowering parasitic capacitances in IC structures by forming an opening within the spacer formed along a sidewall of the semiconductor device. The methods also employ selective epitaxial process to grow an epitaxial silicon layer and form an air gap so that the parasitic capacitances caused by a bit-line coupling effect may be further lowered.

### BRIEF DESCRIPTION OF THE DRAWING

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are cross-sectional views for illustrating a flow of a method for fabricating a semiconductor device according to an embodiment of the present invention.

FIGS. 2A to 2C are cross-sectional views illustrating a process for fabricating a spacer of a semiconductor device according to an embodiment of the present invention.

FIGS. 3A and 3B are cross-sectional views illustrating a method for fabricating a semiconductor device according to another embodiment of the present invention.

FIGS. 4A to 4D are cross-sectional views illustrating a process for fabricating a spacer of a semiconductor device according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

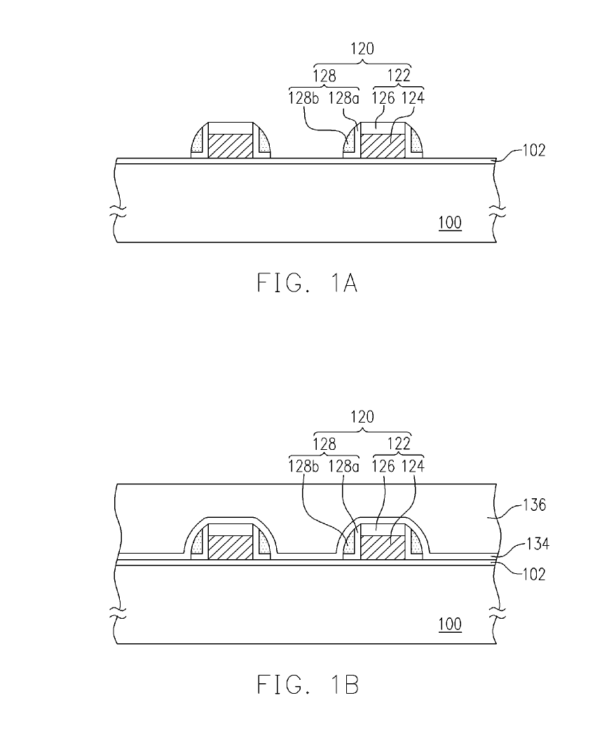

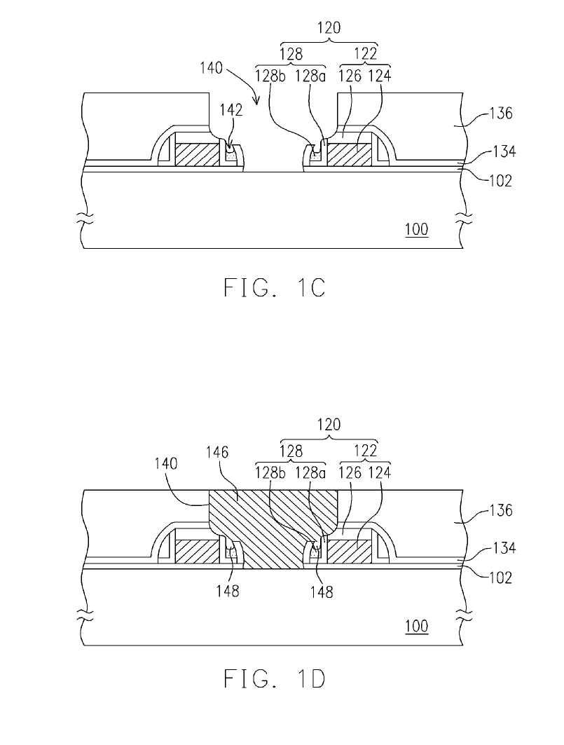

FIGS. 1A to 1D are cross-sectional views illustrating a method for fabricating a semiconductor device according to an embodiment of the present invention. This embodiment is exemplified with a memory cell device. However the present invention is not limited thereto, other semiconductor devices, e.g., metallic-oxide semiconductor (MOS) devices may also be adapted purpose of the present invention.

Referring to FIG. 1A, a thin oxide layer is formed on a substrate 100. The oxide layer serves as a gate dielectric layer 102. The gate dielectric layer 102 is, for example, made of silicon oxide, and may be formed by, for example, a thermal oxidization method or a chemical vapor deposition (CVD) method.

Next, a plurality of gate structures 120 are formed over the substrate 100. Each of the gate structures 120 is composed of a stacked structure 122 and a spacer 128. Each stacked structure 122 includes a gate conductive layer 124 and a cap layer 126 disposed on the gate conductive layer 124. The gate conductive layer 124, for example, is composed of an amorphous silicon layer and a metallic silicide layer, and the cap layer 126, for example, is made of silicon nitride.

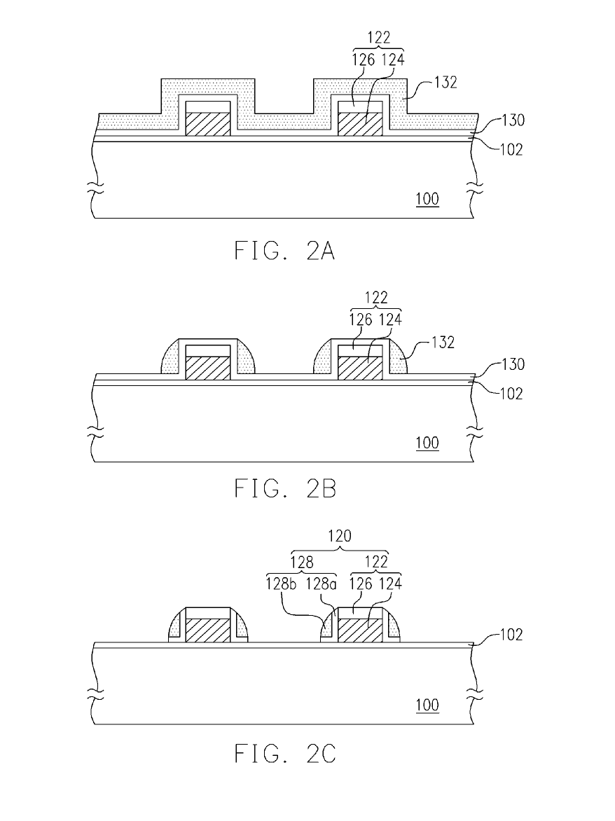

The spacer 128 is formed on a sidewall of the stacked structure 122 and includes a first dielectric layer 128a and a second dielectric layer 128b. The spacer 128 may be formed by a process illustrated in FIGS. 2A to 2C according to an embodiment of the present invention.

Referring to FIG. 2A, a first material layer 130 and a second material layer 132 are sequentially disposed over the substrate 100 covering the stacked structures 122 and the gate dielectric layer 102. The first material layer 130, for example, is made of silicon nitride with a CVD method. The second material layer 132, for example, is made of silicon oxide and may be formed by a CVD process.

Next, referring to FIG. 2B, a portion of the second material layer 132 is removed to expose a portion of the first material layer 130, while a remaining portion of the second material layer 132 on the first material layer 130 is in contact with the sidewall of the stacked structure 122. The portion of the second material layer 132 may be removed, for example, by performing an etching process.

Next, referring to FIG. 2C, the portions of the first material layer 130 not covered by the second material layer 132 are then removed to expose the gate dielectric layer 102. The first dielectric layer 128a and the second dielectric layer 128b thus form a spacer 128 of the gate structure 120.

It is noted that the formation of the spacer 128 is not restricted to the process described above; those skilled in the art may employ any other process to fabricate the spacer to achieve the purpose of the present invention.

Referring to FIG. 1B, after the spacer 128 is formed, a barrier layer 134 is formed over the substrate 100 covering the gate structure 120 and the gate dielectric layer 102. The barrier layer 134 comprises, for example, a silicon nitride and may be formed by, for example, a CVD process. Next, a dielectric layer 136 is formed on the barrier layer 134. The dielectric layer 136 comprises, for example, borophosposilicate glass (BPSG), and may be formed by, for example, depositing a dielectric layer on the barrier layer using a CVD process and then annealing it. Next, a chemical-mechanical polishing process is conducted to obtain the BPSG layer with a substantially flat topography.

Next, referring to FIG. 1C, a self-aligned contact window etching process is conducted to form a contact window opening 140, which exposes a portion of the substrate 100, in a portion of the dielectric layer 136 between a pair of adjacent gate structures 120. The self-aligned contact window etching process, for example, includes the steps of sequentially forming a hard mask layer (not shown) and a patterned photoresist layer (not shown) over the dielectric layer 136, removing a portion of the hard mask layer using the patterned photoresist layer as a mask to expose a portion of the dielectric layer 136, removing the patterned photoresist layer, and forming the contact window opening 140 in the dielectric layer 136 using the hard mask layer as a mask.

It is noted that the self-aligned contact window etching process removes not only the portions of dielectric layer 136 and the gate dielectric layer 102, but also removes portions of the barrier layer 134, the cap layer 126 and the spacer 128. By selecting proper material and the process, a greater proportion of the second dielectric layer 128b may be removed compared to that of the barrier layer 134 and the first dielectric layer 128a. In other words, the removing rate for the second dielectric layer 128b is faster than that for the barrier layer 134 and the first dielectric layer 128a. As such, an opening 142 is formed within the spacer 128 on the sidewall of the stacked structure 122. In this manner, the spacer 128 may have a smaller dielectric constant, and thereby reducing the potential parasitic capacitances induced between the gate conductive layer 124 and the subsequently formed contact window 146.

According to an embodiment of the invention, a pre-clean step is conducted after the contact window opening 140 is formed to remove the residual oxide leaving on the bottom of the contact window opening 140 using, for example, a cleaning solution including a dilute buffered hydrofluoric acid (DBHF).

Referring to FIG. 1D, a selective epitaxial growth (SEG) process is then conducted after the contact window opening 140 is formed. An epitaxial silicon layer is grown in the contact window opening 140 to form a contact window 146. According to an aspect of the embodiment, an in situ doping process is conducted to dope phosphorus atoms or arsenic atoms into the contact window 146. Next, a bit-line (not shown) is formed on the dielectric layer 136, above the gate structure 120 and electrically connecting with the contact window 146. Thereafter, other processes may be carried out to complete a memory device that are well known to those skilled in the art and will not be described herein.

It should be noted that during the SEG process, the epitaxial silicon layer is isotropic grown upwardly from a surface of the substrate corresponding to the bottom of the contact window 140. That is, the epitaxial silicon layer is not formed backwardly and does not fill into the opening 142. Thus, an air gap 148 is formed therein, and thereby lowering the parasitic capacitance caused by the bit-line coupling effect.

Furthermore, the method for fabricating a memory cell device according to the embodiment of the present invention is compatible with processes for fabricating peripheral circuit regions, by which a memory cell device comprising a memory cell region and a peripheral circuit region in a single chip may be fabricated.

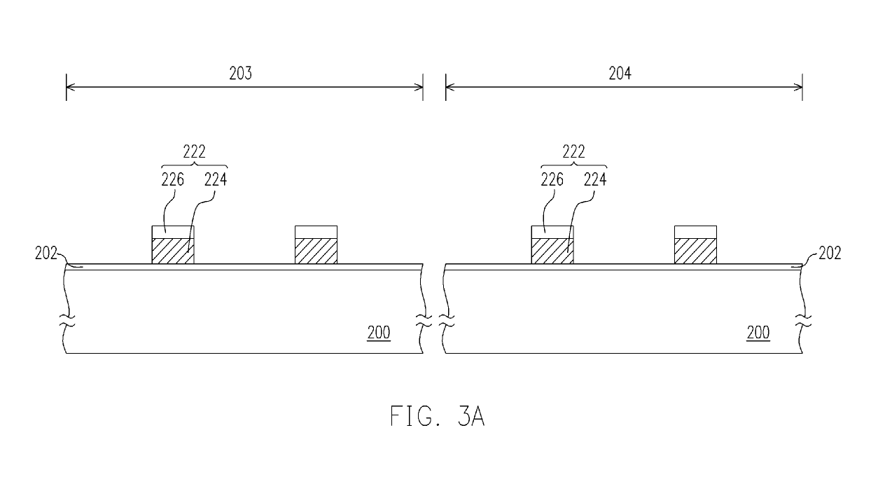

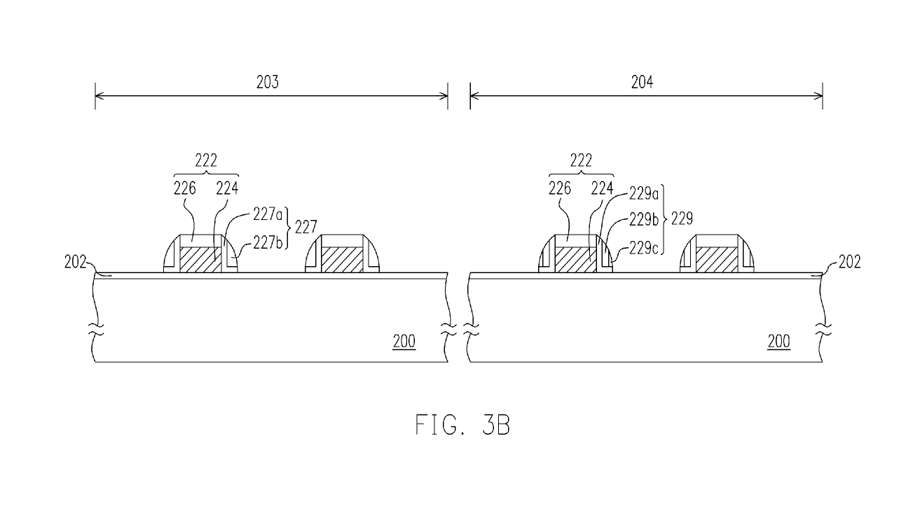

FIGS. 3A and 3B are cross-sectional views illustrating a method for fabricating a semiconductor device according to another embodiment of the present invention.

Referring to FIG. 3A, a substrate 200 having a memory cell region 203 and a peripheral circuit region 204 is provided. Next, a thin oxide layer is formed on a surface of the substrate 200. The oxide layer serves as a gate dielectric layer 202. The gate dielectric layer 202 comprises, for example, silicon oxide, and may be formed by, for example, a thermal oxidization process or a chemical vapor deposition (CVD) process.

Next, a plurality of stacked structures 222 are formed over the substrate 200, each of which are composed of a gate conductive layer 224 and a cap layer 226. The gate conductive layer 224, for example, is composed of an amorphous silicon layer and a metallic silicide layer, and the cap layer 226, for example, is composed of silicon nitride.

Referring to FIG. 3B, a first spacer 227 is formed on a sidewall of the stacked structure 222 of the memory cell region 203, and a second spacer 229 is formed on a sidewall of the stacked structure 222 of the peripheral circuit region 204. The first spacer 227 includes a first dielectric layer 227a and a second dielectric layer 227b, and the second spacer 229 includes a third dielectric layer 229a, a fourth dielectric layer 229b and a fifth dielectric layer 229c.

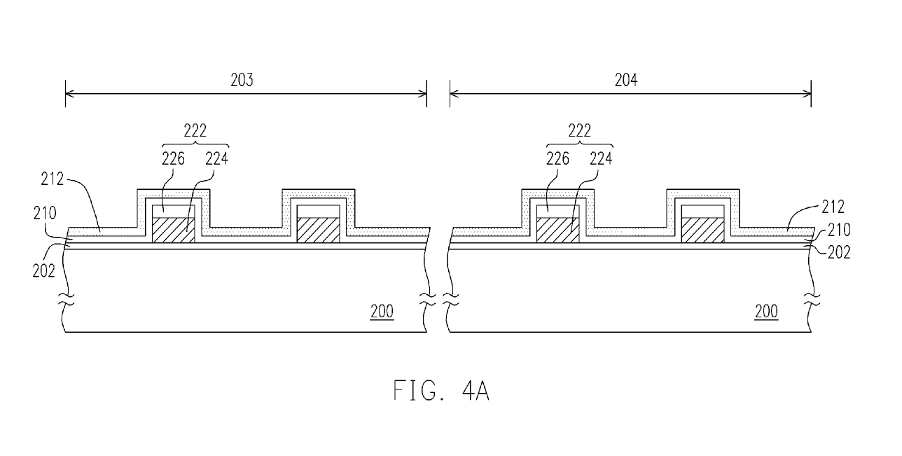

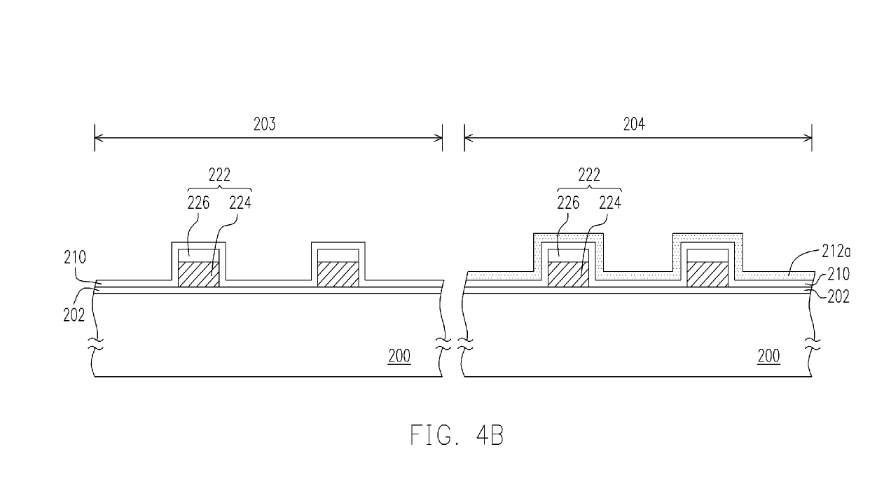

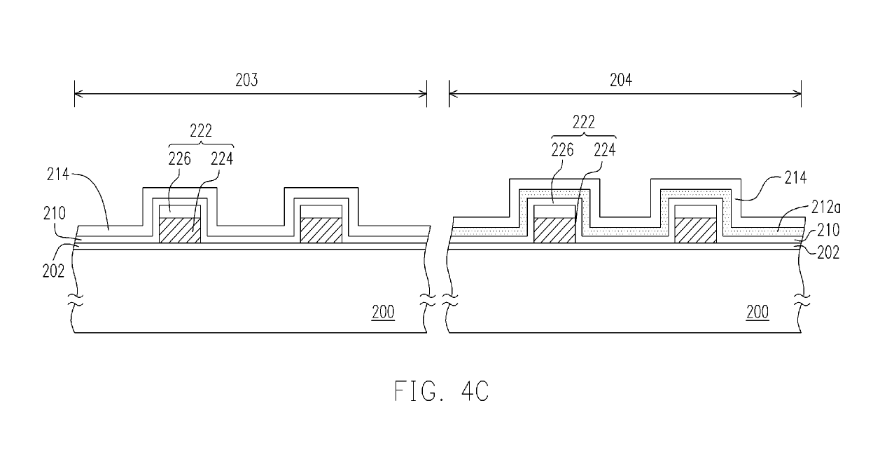

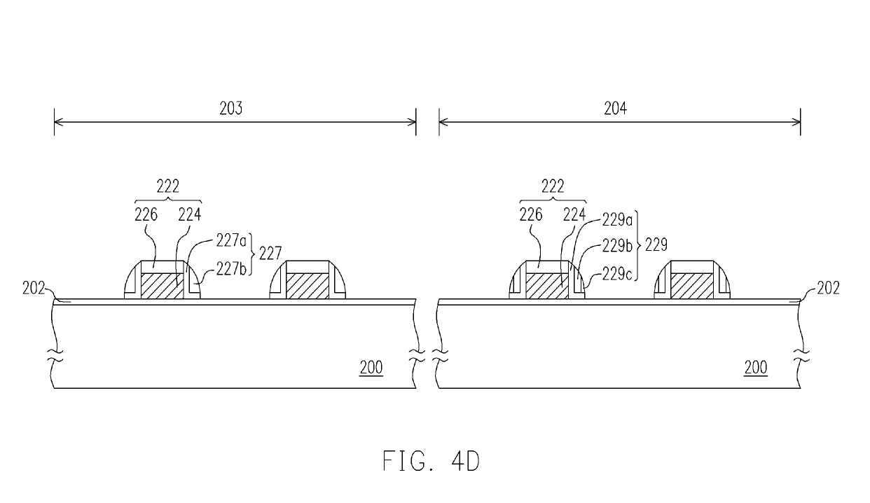

A process for forming the spacers 227 and 229 is illustrated by FIGS. 4A to 4D according to another embodiment of the present invention.

Referring to FIG. 4A, a first material layer 210 and a second material layer 212 are sequentially disposed on the substrate 200 covering the stacked structures 222 and the gate dielectric layer 202. The first material layer 210, for example, is composed of silicon nitride and may be formed by performing, for example, a CVD process. The second material layer 212, for example, is composed of silicon oxide and may be formed by performing, for example, a CVD process.

Next, referring to FIG. 4B, a portion of the second material layer 212 of the memory cell region 203 is removed to expose a portion of the first material layer 210 so that a remaining portion of the second material layer 212a is retained in the peripheral circuit region 204. The method for removing the second material layer 212 of the memory cell region 203, for example, includes using an isotropic etching process.

Next, referring to FIG. 4C, a third material layer 214 is formed covering the first material layer 210 and the second material layer 212a. The third material layer 214, for example, is composed of silicon oxide and may be formed by performing a CVD process.

Next, referring to FIG. 4D, portions of the third material layer 214 and the second material layer 212a are removed to expose a portion of the first material layer 210. Thereafter, a portion of the first material layer 210 not covered by the third material layer 214 is removed to expose a portion of the gate dielectric layer 202. As such, a first dielectric layer 227a, a second dielectric layer 227b are formed on a sidewall of the stacked structure 222 in the memory cell region 203, and a third dielectric layer 229a, a fourth dielectric layer 229b and a fifth dielectric layer 229c are formed on a sidewall of the stacked structure 222 in the peripheral circuit region 204. The first dielectric layer 227a and the second dielectric layer 227b constitute the first spacer 227, and the third dielectric layer 229a, the fourth dielectric layer 229b and the fifth dielectric layer 229c constitute the second spacer 229.

Referring to FIG. 3B, some processes as described in FIG. 1B through 1D may be continued. For example, a barrier layer (not shown) is formed on the substrate 200 covering the stacked structures 222 and the gate dielectric layer 202. Next, a dielectric layer (not shown) is formed on the barrier layer. Thereafter, a self-aligned contact window etching process is conducted to form a contact window opening (not shown) in a portion of the dielectric layer (not shown) between a pair of adjacent stacked structures 222 in the memory cell region 203; wherein the contact window opening exposes a portion of the substrate 200. After the contact window opening is formed, an SEG process is conducted to grow an epitaxial silicon layer in the contact window opening to form a contact window (not shown). Next, a bit-line is formed on the dielectric layer, over the stacked structures 222 and electrically connecting with the contact window. Thereafter, other processes for fabricating the memory device are carried out, which are well known to those skilled in the art and will not be described herein.

According to the foregoing methods, an opening is formed in the spacer formed on a sidewall of the semiconductor device so that the spacer has a lower dielectric constant. Thus, the parasitic capacitances in the IC structure may be effectively reduced. Moreover, an SEG process is employed for growing an epitaxial silicon layer to form the contact window such that an air gap is formed within the opening, and thereby decreasing the parasitic capacitance caused by the bit-line coupling effect.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a semiconductor device, comprising:
forming a gate dielectric layer on a substrate;
forming a plurality of gate structures on the gate dielectric layer, each of the gate structures comprising a stacked structure and a spacer formed on a sidewall of the stacked structure, each stacked structure comprising a gate conductive layer and a cap layer, the spacer comprising a first dielectric layer and a second dielectric layer;
forming a barrier layer over the substrate covering conformally the gate structures and the gate dielectric layer;
forming a dielectric layer on the barrier layer;
performing an self-aligned contact window etching process to form a contact window opening in a portion of the dielectric layer between a pair of adjacent gate structures, the contact window opening exposing a portion of the substrate, wherein portions of the dielectric layer, the barrier layer, the cap layer, the gate dielectric layer and the spacer are removed to form an opening in the second dielectric layer; and
performing a selective epitaxial growth process on a surface of the substrate exposed by the contact window opening to grow an epitaxial silicon layer, and to form an air gap in the opening.

2. The method for fabricating a semiconductor device according to claim 1, wherein the first dielectric layer comprises silicon nitride.

3. The method for fabricating a semiconductor device according to claim 1, wherein the second dielectric layer comprises silicon oxide.

4. The method for fabricating a semiconductor device according to claim 1, wherein the barrier layer comprises silicon nitride.

5. The method for fabricating a semiconductor device according to claim 1, wherein the step of forming the spacer comprises:
sequentially forming a first material layer and a second material layer over the substrate covering the stacked structures and the gate dielectric layer;
removing a portion of the second material layer to expose a portion of the first material layer; and
removing a portion of the first material layer uncovered by the second material layer to expose a portion of the gate dielectric layer.

6. The method for fabricating a semiconductor device according to claim 1, further comprising performing a pre-clean step after the contact window opening is formed.

7. A method for fabricating a semiconductor device, comprising:
providing a substrate having a memory cell region and a peripheral circuit region;
forming a gate dielectric layer over the substrate;
forming a plurality of stacked structures on the substrate, each of the stacked structures comprising a gate conductive layer and a cap layer;
forming a first spacer on a sidewall of each of the stacked structures in the memory cell region, and forming a second spacer on a sidewall of each of the stacked structures in the peripheral circuit region, wherein the first spacer comprises a first dielectric layer and a second dielectric layer sequentially disposed on the sidewall of the stacked structure in the memory cell region, and the second spacer comprises a third dielectric layer, a fourth dielectric layer and a fifth dielectric layer sequentially disposed on the sidewall of the stacked structure in the peripheral circuit region;
forming a barrier layer over the substrate covering the stacked structures, the first spacer, the second spacer and the gate dielectric layer;
forming a dielectric layer on the barrier layer;
performing an self-aligned contact window etching process to form a contact window opening in a portion of the dielectric layer between a pair of adjacent stacked structures in the memory cell region, the contact window opening exposing a portion of the substrate, wherein portions of the dielectric layer, the barrier layer, the cap layer, the gate dielectric layer and the first spacer are removed to form an opening in the second dielectric layer; and
performing a selective epitaxial growth process on a surface of the substrate exposed by the contact window opening to grow an epitaxial silicon layer to form a contact window within the contact window opening and an air gap in the opening.

8. The method for fabricating a semiconductor device according to claim 7, wherein the first dielectric layer and the third dielectric layer comprise silicon nitride.

9. The method for fabricating a semiconductor device according to claim 7, wherein the second dielectric layer comprises silicon oxide.

10. The method for fabricating a semiconductor device according to claim 7, wherein the fourth dielectric layer and the fifth dielectric layer comprise silicon oxide.

11. The method for fabricating a semiconductor device according to claim 7, wherein the barrier layer comprises silicon nitride.

12. The method for fabricating a semiconductor device according to claim 7, wherein the step of forming the first spacer and the second spacer comprises:
forming a first material layer and a second material layer in turn on the substrate covering the stacked structures and the gate dielectric layer;
removing a portion of the second material layer in the memory cell region to expose a portion of the first material layer;
forming a third material layer covering the first material layer and the second material layer;
removing portions of the third material layer and the second material layer to expose a portion of the first material layer; and
removing a portion of the first material layer uncovered by the third material layer to expose a portion of the gate dielectric layer.

13. The method for fabricating a semiconductor device according to claim 7, further comprising performing a pre-clean step after the contact window opening is formed.

14. A method for fabricating a semiconductor device, comprising:
forming a first gate structure and a second gate structure over a substrate, the first gate structure and the second gate structure respectively comprising a gate conductive layer, a first dielectric layer formed on a sidewall of the gate conductive layer, and a second dielectric layer formed on the first dielectric layer;
forming a barrier layer over the substrate covering the first gate structure and the second gate structure;
forming a dielectric layer on the barrier layer;
removing portions of the dielectric layer and the barrier layer between the first gate structure and the second gate structure to expose a surface of the substrate and define a first opening between the first gate structure and the second gate structure, and removing portions of the first dielectric layer, the second dielectric layer and the barrier layer between the first gate structure and the second gate structure to define a second opening between the first dielectric layer and the barrier layer, wherein a rate to remove the second dielectric layer is faster than a rate to remove the first dielectric layer and the barrier layer; and
performing a selective epitaxial growth process on a surface of the substrate exposed by the first opening to grow an epitaxial silicon layer, wherein the epitaxial silicon layer partially fills the first opening and an air gap is formed in the second opening.

15. The method for fabricating a semiconductor device according to claim 14, wherein the first dielectric layer comprises silicon nitride.

16. The method for fabricating a semiconductor device according to claim 14, wherein the second dielectric layer comprises silicon oxide.

17. The method for fabricating a semiconductor device according to claim 14, wherein the barrier layer comprises silicon nitride.

18. The method for fabricating a semiconductor device according to claim 14, further comprising performing a pre-clean step prior to forming the epitaxial silicon layer.
